(19) United States
(12) Patent Application Publication
(10) Pub. No.: US 2026/0215130 A1
(43) Pub. Date: Jul. 23, 2026

(54) Display Device and Method of Manufacturing the Same

(71) Applicant: LG Display Co., Ltd., Seoul (KR)

(72) Inventor: Hong Myeong Jeon, Paju-si (KR)

(21) Appl. No.: 19/378,167

(22) Filed: Nov. 3, 2025

(30) Foreign Application Priority Data
Jan. 17, 2025 (KR) 10-2025-0007359

(51) Int. Cl. H10K 59/80; H10K 59/12; H10K 59/121; H10K 59/131; H10K 71/00

(52) U.S. Cl. CPC H10K 59/8722; H10K 59/1201; H10K 59/121; H10K 59/131; H10K 71/851

(57) ABSTRACT

A display device presented herein includes an element substrate, an active area including a pixel drive circuit and a light emitting element located on the element substrate, a pad area located on the element substrate, and a cover substrate located on the element substrate. The cover substrate is configured to cover the active area and the pad area. The cover substrate includes an open area configured to expose the pad area and a residual adhesive layer remaining on a side surface of the open area.

### CROSS-REFERENCE TO RELATED APPLICATION

The present application claims priority to Republic of Korea Patent Application No. 10-2025-0007359, filed on January 17, 2025, which is hereby incorporated by reference in its entirety.

### BACKGROUND

### Field

The present disclosure relates to a display device and a method of manufacturing the same.

### Discussion of the Related Art

As information technology advances, the market for display devices, which are the medium of connection between users and information, is growing. Accordingly, the use of display devices, such as a light emitting display device (LED), a quantum dot display device (QDD), and a liquid crystal display device (LCD), is increasing.

Each of the display devices includes a display panel including subpixels, a drive unit configured to output a drive signal for driving the display panel, and a power supply unit configured to generate power to be supplied to the display panel or the drive unit.

Each of the display devices may be configured such that, when drive signals, such as scan signals and data signals, are supplied to the subpixels formed on the display panel, the selected subpixels transmit light or emit light directly, thereby displaying an image.

### SUMMARY

Embodiments of the present disclosure simplify a process involved in manufacturing a display panel based on a method for processing a cover substrate using an LMCE process, thereby reducing equipment investment costs while improving productivity and quality. Embodiments of the present disclosure simplify a cutting process based on open areas formed on the cover substrate, thereby reducing processing time, and it is possible to simplify the process such that some steps of the process can be omitted. Embodiments of the present disclosure allow an adhesive layer or a resin layer used during lamination between display cells cut into cell units to remain in the open areas formed on the cover substrate, thereby protecting pad areas from foreign substances as well as enhancing protection against external air by preventing moisture penetration.

A display device according to one or more embodiments of the present disclosure includes an element substrate, an active area including a pixel drive circuit and a light emitting element located on the element substrate, a pad area located on the element substrate, and a cover substrate located on the element substrate, the cover substrate being configured to cover the active area and the pad area, wherein the cover substrate includes an open area configured to expose the pad area and a residual adhesive layer remaining on a side surface of the open area.

The residual adhesive layer may be made of the same material as an adhesive layer configured to facilitate lamination between the element substrate and the cover substrate.

The residual adhesive layer has an area equal to or less than the area of the open area.

The display device may include a resin layer formed on the side surface of the open area and located on the residual adhesive layer.

A method of manufacturing a display device according to one or more embodiments of the present disclosure includes forming an active area including a pixel drive circuit and a light emitting element and a pad area electrically connected to the active area on an element substrate in plural as a display cell unit, forming an adhesive layer configured to cover the active area and the pad area on the element substrate, aligning a cover substrate on the element substrate and laminating the element substrate and the cover substrate using the adhesive layer, and performing a cutting process to cut the element substrate and the cover substrate so as to be separated as the display cell unit, wherein the cover substrate includes an open area configured to expose the pad area and a residual adhesive layer remaining on a side surface of the open area.

The residual adhesive layer may be made of the same material as the adhesive layer configured to facilitate lamination between the element substrate and the cover substrate.

The cover substrate may include a plurality of open lines provided so as to correspond to an area defined as a cutting line during the cutting process, and the open lines may be implemented so as to be formed through the cover substrate.

The cover substrate may include a plurality of cutting lines provided so as to correspond to an area defined as a cutting line during the cutting process, and the cutting lines may be implemented in a shape of recesses that are not formed through the cover substrate.

The residual adhesive layer may have an area equal to or less than the area of the open area.

The display device may include a resin layer formed on the side surface of the open area and located on the residual adhesive layer.

The object and technical configuration of the present disclosure and the effects based thereon will be more clearly understood from the following detailed description with reference to the accompanying drawings, which show embodiments of the present disclosure. The embodiments of the present disclosure are provided to enable the technical ideas of the present disclosure to be fully conveyed to those skilled in the art, and the present disclosure may be embodied in other forms without limitation to the embodiments described herein.

In addition, throughout the specification, the same components are denoted by the same reference numerals, and in the drawings, the lengths and thicknesses of layers or areas may be exaggerated for convenience. Furthermore, when a first component is described as being “on” a second component, this includes not only the case in which the first component is located on the second component in direct contact therewith but also the case in which a third component is located between the first and second components.

Terms such as “first” and “second” may be used herein to describe various components, and are used to distinguish one component from another component. However, a first component and a second component may be arbitrarily named according to the convenience of those skilled in the art without departing from the scope of the present disclosure.

The terms used in the present disclosure are provided only to describe specific embodiments, and do not limit the present disclosure. Singular forms are intended to include plural forms as well, unless the context clearly indicates otherwise. In the present disclosure, it should be understood that the terms “includes,” “has,” etc. specify the presence of stated features, numbers, steps, operations, elements, components, or combinations thereof, but do not preclude the presence or addition of one or more other features, numbers, steps, operations, elements, components, or combinations thereof.

In addition, all terms, including technical and scientific terms, have the same meanings as those commonly understood by one of ordinary skill in the art to which the present disclosure pertains, unless defined otherwise. Commonly used terms, such as those defined in typical dictionaries, should be interpreted as being consistent with the contextual meaning of the relevant art, and are not to be construed in an ideal or overly formal sense unless expressly defined to the contrary.

FIG. 1 is a schematic view of a display device according to one or more embodiments of the present disclosure. FIG. 2 is an enlarged view of area K1 in FIG. 1. FIG. 3 is a view showing a circuit of a pixel area in the display device according to one or more embodiments of the present disclosure. FIG. 4 is a sectional view taken along line I-I’ in FIG. 2.

Referring to FIGS. 1 to 4, the display device according to one or more embodiments of the present disclosure may include a display panel DP. The display panel DP may generate an image to be provided to a user. For example, pixel areas PA may be located in the display panel DP. Various signals may be applied to the pixel areas PA through signal lines GL, DL, and PL. The signal lines GL, DL, and PL may include a gate line GL for applying a gate signal, a data line DL for applying a data signal, and a power voltage supply line PL for supplying a power voltage.

The display panel DP may include an active area AA where the pixel areas PA are located and a bezel area BZ located outside the active area AA. The signal lines GL, DL, and PL may be electrically connected to the pixel areas PA via the bezel area BZ. For example, the active area AA may be surrounded by the bezel area BZ. A gate drive circuit GD electrically connected to the gate line GL, a data drive circuit DD electrically connected to the data line DL, a power supply circuit PU electrically connected to the power voltage supply line PL, and a timing control circuit TC configured to control the gate drive circuit GD and the data drive circuit DD may be located outside the active area AA. At least one of the gate drive circuit GD, the data drive circuit DD, the power supply circuit PU, and the timing control circuit TC may be located in the bezel area BZ. For example, the display device according to one or more embodiments of the present disclosure may be a gate in panel (GIP) type display device in which the gate drive circuit GD is formed in the bezel area BZ.

Each pixel area PA may implement a specific color. For example, a pixel drive circuit DC electrically connected to the signal lines GL, DL, and PL and a light emitting element 300 electrically connected to the pixel drive circuit DC may be located in each pixel area PA. The pixel drive circuit DC and the light emitting element 300 of each pixel area PA may be supported by an element substrate 100. The element substrate 100 may include various materials. For example, the element substrate 100 may be a wafer made of a semiconductor material such as silicon.

The pixel drive circuit DC may supply a drive current corresponding to a data signal to the light emitting element 300 in accordance with a gate signal using power voltage. The drive current supplied to the light emitting element 300 by the pixel drive circuit DC may be maintained for one frame. For example, the pixel drive circuit DC may include a first thin film transistor TR1, a second thin film transistor TR2, and a storage capacitor Cst.

The first thin film transistor TR1 may transmit a data signal to the second thin film transistor TR2 in accordance with a gate signal. For example, the first thin film transistor TR1 may function as a switching thin film transistor. The first thin film transistor TR1 may include a first well area, a first drain area, a first source area, a first gate electrode, a first drain electrode, and a first source electrode. For example, the first gate electrode may be electrically connected to the gate line GL, and the first drain electrode may be electrically connected to the data line DL.

The second thin film transistor TR2 may generate a drive current corresponding to a data signal using power voltage. For example, the second thin film transistor TR2 may function as a drive thin film transistor. The second thin film transistor TR2 may include a second well area 102w, a second drain area 102d, a second source area 102s, a second gate electrode 223, a second drain electrode 225, and a second source electrode 227. For example, the second gate electrode 223 may be electrically connected to the first source electrode, and the second drain electrode 225 may be electrically connected to the power voltage supply line PL.

The second well area 102w, the second drain area 102d, and the second source area 102s may be formed in the element substrate 100. Each of the second well area 102w, the second drain area 102d, and the second source area 102s may include a conductive dopant. For example, a process for forming the second well area 102w, the second drain area 102d, and the second source area 102s may include a process for doping a part of the element substrate 100 with a conductive dopant. The second drain area 102d and the second source area 102s may include a different type of conductive dopant than the second well area 102w. For example, the second well area 102w may include an N-type dopant, and each of the second drain area 102d and the second source area 102s may include a P-type dopant. The second drain area 102d and the second source area 102s may be located in the second well area 102w.

The second well area 102w may include a different type of conductive dopant than the first well area. Each of the second drain area 102d and the second source area 102s may include a different type of conductive dopant than the first drain area and the first source area. For example, the second well area 102w may include the same type of conductive dopant as the first drain area and the first source area, and each of the second drain area 102d and the second source area 102s may include the same type of conductive dopant as the first well area. Accordingly, in the display device according to one or more embodiments of the present disclosure, the second thin film transistor TR2 may have different characteristics than the first thin film transistor TR1. The second well area 102w may be formed simultaneously with the first drain area and the first source area, and the second drain area 102d and the second source area 102s may be formed simultaneously with the first well area. Therefore, in the display device according to one or more embodiments of the present disclosure, process efficiency may be improved.

The second gate electrode 223 may be located on the element substrate 100. For example, the second gate electrode 223 may overlap a part of the second well area 102w. The second gate electrode 223 may include a conductive material. For example, the second gate electrode 223 may include a metal such as aluminum (Al), chromium (Cr), copper (Cu), molybdenum (Mo), titanium (Ti), or tungsten (W). A part of the second well area 102w overlapping the second gate electrode 223 may be located between the second drain area 102d and the second source area 102s. The second gate electrode 223 may be spaced apart from the element substrate 100. The second gate electrode 223 may be insulated from the element substrate 100. For example, a part of the second well area 102w overlapping the second gate electrode 223 between the second drain area 102d and the second source area 102s may have an electrical conductivity corresponding to the voltage of z signal applied to the second gate electrode 223. A part of the second well area 102w overlapping the second gate electrode 223 between the second drain area 102d and the second source area 102s may function as a channel area of the second thin film transistor TR2.

The second gate electrode 223 may include the same material as the first gate electrode. The second gate electrode 223 may be located on the same layer as the first gate electrode. The second gate electrode 223 may be formed through the same process as the first gate electrode. For example, the second gate electrode 223 may be formed simultaneously with the first gate electrode.

The second drain electrode 225 may be located on the element substrate 100. The second drain electrode 225 may be electrically connected to the second drain area 102d. The second drain electrode 225 may include a conductive material. For example, the second drain electrode 225 may include a metal such as aluminum (Al), chromium (Cr), copper (Cu), molybdenum (Mo), titanium (Ti), or tungsten (W). The second drain electrode 225 may be spaced apart from the element substrate 100. The second drain electrode 225 may be insulated from the second gate electrode 223. For example, the second drain electrode 225 may be located on a different layer from the second gate electrode 223. The second drain electrode 225 may include a different material from the second gate electrode 223.

The second drain electrode 225 may include the same material as the first drain electrode. The second drain electrode 225 may be located on the same layer as the first drain electrode. The second drain electrode 225 may be formed through the same process as the first drain electrode. For example, the second drain electrode 225 may be formed simultaneously with the first drain electrode.

The second source electrode 227 may be located on the element substrate 100. The second source electrode 227 may be electrically connected to the second source area 102s. The second source electrode 227 may include a conductive material. For example, the second source electrode 227 may include a metal such as aluminum (Al), chromium (Cr), copper (Cu), molybdenum (Mo), titanium (Ti), or tungsten (W). The second source electrode 227 may be spaced apart from the element substrate 100. The second source electrode 227 may be insulated from the second gate electrode 223. For example, the second source electrode 227 may be located on a different layer from the second gate electrode 223. The second source electrode 227 may include a different material from the second gate electrode 223.

The second source electrode 227 may be located on the same layer as the second drain electrode 225. The second source electrode 227 may include the same material as the second drain electrode 225. The second source electrode 227 may be formed through the same process as the second drain electrode 225. For example, the second source electrode 227 may be formed simultaneously with the second drain electrode 225. The second source electrode 227 may be spaced apart from the second drain electrode 225.

The second source electrode 227 may include the same material as the first source electrode. The second source electrode 227 may be located on the same layer as the first source electrode. The second source electrode 227 may be formed through the same process as the first source electrode. For example, the second source electrode 227 may be formed simultaneously with the first source electrode.

The storage capacitor Cst may maintain the voltage of a signal applied to the second gate electrode 223 for one frame. The storage capacitor Cst may have a stack structure of capacitor electrodes. For example, the storage capacitor Cst may have a structure in which a first capacitor electrode electrically connected to the second gate electrode 223 and a second capacitor electrode electrically connected to the second source electrode are stacked. The storage capacitor Cst may be formed using the process for forming the first thin film transistor TR1 and the second thin film transistor TR2. For example, the first capacitor electrode may be formed simultaneously with the second gate electrode 223, and the second capacitor electrode may be formed simultaneously with the second source electrode 227. Accordingly, in the display device according to one or more embodiments of the present disclosure, process efficiency may be improved.

At least one insulating layer 110, 120, 130, and 140 configured to prevent unnecessary electrical connection may be provided on the element substrate 100. For example, a gate insulating layer 110, an interlayer insulating layer 120, an element planarization layer 130, and fences 140 may be located on the element substrate 100.

The gate insulating layer 110 may be located close to the element substrate 100. The second gate electrode 223 in each pixel area PA may be insulated from the element substrate 100 by the gate insulating layer 110. For example, the first gate electrode and the second gate electrode 223 in each pixel area PA may be located on the gate insulating layer 110 that completely covers an upper surface of the element substrate 100. The gate insulating layer 110 may include an insulating material. For example, the gate insulating layer 110 may be an inorganic insulating layer made of an inorganic insulating material such as silicon oxide (SiOx) or silicon nitride (SiNx). The second gate electrode 223 in each pixel area PA may have the same level as the first gate electrode in each pixel area PA. For example, the distance between the element substrate 100 and the second gate electrode 223 in each pixel area PA may be the same as the distance between the element substrate 100 and the first gate electrode in each pixel area PA. The gate insulating layer 110 may be a linear insulating layer having a certain thickness.

The interlayer insulating layer 120 may be located on the gate insulating layer 110. The second drain electrode 225 and second source electrode 227 in each pixel area PA may be insulated from the second gate electrode 223 in the pixel area PA by the interlayer insulating layer 120. For example, the interlayer insulating layer 120 may cover the first gate electrode and the second gate electrode 223 in each pixel area PA. The first drain electrode, the first source electrode, the second drain electrode 225, and the second source electrode 227 in each pixel area PA may be located on the interlayer insulating layer 120. The interlayer insulating layer 120 may include an insulating material. For example, the interlayer insulating layer 120 may be an inorganic insulating layer made of an inorganic insulating material such as silicon oxide (SiOx) or silicon nitride (SiNx).

The element planarization layer 130 may be located on the interlayer insulating layer 120. The element planarization layer 130 may eliminate the height difference caused by the pixel drive circuit DC in each pixel area PA. For example, the first drain electrode, the first source electrode, the second drain electrode 225, and the second source electrode 227 in each pixel area PA may be covered by the element planarization layer 130. An upper surface of the element planarization layer 130 opposite the element substrate 100 may be flat. For example, the upper surface of the element planarization layer 130 may be parallel to the upper surface of the element substrate 100. The element planarization layer 130 may include an insulating material. The element planarization layer 130 may include a material having high fluidity. For example, the element planarization layer 130 may be an organic insulating layer made of an organic insulating material. The element planarization layer 130 may include a first planarization layer 131, a second planarization layer 132, a third planarization layer 133, and a fourth planarization layer 134 stacked in order; however, the present disclosure is not limited thereto.

The light emitting element 300 in each pixel area PA may be located on the element planarization layer 130. The light emitting element 300 in each pixel area PA may emit light of a specific color. For example, the light emitting element 300 in each pixel area PA may include a lower electrode 310, a light emitting unit 320, and an upper electrode 330 stacked on the element planarization layer 130 in order.

Each of the lower electrode 310 and the upper electrode 330 may include a conductive material. The upper electrode 330 may include a different material from the lower electrode 310. For example, the lower electrode 310 may be a transparent electrode made of a transparent conductive material such as ITO or IZO, and the upper electrode 330 may be a semi-transparent electrode made of a thin metal such as silver (Ag) or magnesium (Mg). The upper electrode 330 may have a different work function from the lower electrode 310. For example, the work function of the upper electrode 330 may be lower than that of the lower electrode 310. Accordingly, in the display device according to one or more embodiments of the present disclosure, the lower electrode 310 may function as an anode, and the upper electrode 330 may function as a cathode.

The light emitting unit 320 may generate light with a luminance corresponding to the voltage difference between the lower electrode 310 and the upper electrode 330. For example, the light emitting unit 320 may include an emission material layer (EML). The emission material layer may include an organic emission material, an inorganic emission material, or a hybrid emission material. For example, the display device according to one or more embodiments of the present disclosure may be an organic light emitting display device including an organic emission material.

The light emitting unit 320 may have a multilayer structure. For example, the light emitting unit 320 may further include at least one of a hole injection layer (HIL), a hole transport layer (HTL), an electron transport layer (ETL), and an electron injection layer (EIL). Accordingly, in the display device according to one or more embodiments of the present disclosure, the efficiency of the light emitting unit 320 may be improved.

The fences 140 may be located on the element planarization layer 130. Each of the fences 140 may include an insulating material. Each fence 140 may have a certain thickness. For example, each of the fences 140 may be an inorganic insulating layer made of an inorganic insulating material. The fences 140 may define emission areas R-EA, G-EA, and B-EA in each pixel area PA. The emission areas R-EA, G-EA, and B-EA of each pixel area PA may refer to areas where light is emitted. For example, in the emission areas R-EA, G-EA, and B-EA of each pixel area PA, the light emitting unit 320 may be in direct contact with the lower electrode 310 and the upper electrode 330.

The lower electrode 310 in each pixel area PA may be spaced apart from the lower electrode 310 in an adjacent pixel area PA. The lower electrode 310 in each pixel area PA may be insulated from the lower electrode 310 in an adjacent pixel area PA by the fences 140. For example, an edge of the lower electrode 310 located in each pixel area PA may be covered by the fences 140. A part of the lower electrode 310 overlapping the emission areas R-EA, G-EA, and B-EA of each pixel area PA may be in direct contact with the upper surface of the element planarization layer 130.

A drive current generated by the pixel drive circuit DC in each pixel area PA may be applied to the lower electrode 310 in the pixel area PA. For example, the lower electrode 310 in each pixel area PA may be in direct contact with the second source electrode 227 in the pixel area PA through the element planarization layer 130. The connection point between the lower electrode 310 and the second source electrode 227 located in each pixel area PA may be located outside the emission areas R-EA, G-EA, and B-EA defined in the pixel area PA. For example, the connection point between the lower electrode 310 and the second source electrode 227 located in each pixel area PA may overlap one of the fences 140. Accordingly, in the display device according to one or more embodiments of the present disclosure, luminance variation caused by the position of generation of light emitted from the emission areas R-EA, G-EA, and B-EA of each pixel area PA may be prevented.

The light generated by the light emitting unit 320 in each pixel area PA may exhibit the same color as the light generated by the light emitting unit 320 in an adjacent pixel area PA. For example, the light emitting unit 320 in each pixel area PA may generate white light. The light emitting unit 320 in each pixel area PA may have the same stack structure as the light emitting unit 320 in an adjacent pixel area PA. For example, the emission material layer in each pixel area PA may include the same material as the emission material layer in an adjacent pixel area PA. The light emitting unit 320 in each pixel area PA may be formed simultaneously with the light emitting unit 320 in an adjacent pixel area PA.

A signal applied to the upper electrode 330 in each pixel area PA may be the same as the signal applied to the upper electrode 330 in an adjacent pixel area PA. For example, the upper electrode 330 in each pixel area PA may be electrically connected to the upper electrode 330 in an adjacent pixel area PA. The upper electrode 330 in each pixel area PA may include the same material as the upper electrode 330 in an adjacent pixel area PA. The upper electrode 330 in each pixel area PA may be formed through the same process as the upper electrode 330 in an adjacent pixel area PA. For example, the upper electrode 330 in each pixel area PA may be formed simultaneously with the upper electrode 330 in an adjacent pixel area PA. The upper electrode 330 in each pixel area PA may be in direct contact with the upper electrode 330 in an adjacent pixel area PA. Accordingly, in the display device according to one or more embodiments of the present disclosure, a process for forming the upper electrode 330 in each pixel area PA may be simplified.

An image provided to the user by the light emitted from the emission areas R-EA, G-EA, and B-EA of the pixel areas PA may include various colors. For example, the emission areas R-EA, G-EA, and B-EA of each pixel area PA may be a red emission area R-EA that emits red light indicating red, a green emission area G-EA that emits green light indicating green, and a blue emission area B-EA that emits blue light indicating blue. A micro-cavity structure may be formed in the emission areas R-EA, G-EA, and B-EA of each pixel area PA. For example, reflective electrodes 200R, 200G, and 200B may be located between the pixel drive circuit DC and the lower electrode 310 in each pixel area PA.

Accordingly, in the display device according to one or more embodiments of the present disclosure, a part of the light generated by the light emitting unit 320 in each pixel area PA having a wavelength range corresponding to the color implemented by the emission areas R-EA, G-EA, and B-EA of the pixel area PA may be amplified between the reflective electrodes 200R, 200G, and 200B and the upper electrode 330 in the pixel area PA. For example, in the display device according to one or more embodiments of the present disclosure, red light may be amplified between the red reflective electrode 200R in the red emission area R-EA and the upper electrode 330, green light may be amplified between the green reflective electrode 200G in the green emission area G-EA and the upper electrode 330, and blue light may be amplified between the blue reflective electrode 200B in the blue emission area B-EA and the upper electrode 330. The light amplified between the reflective electrodes 200R, 200G, and 200B and the upper electrode 330 in each pixel area PA may be emitted through the upper electrode 330 in the pixel area PA.

The positions of the reflective electrodes 200R, 200G, and 200B in the emission areas R-EA, G-EA, and B-EA of each pixel area PA may vary depending on the colors implemented by the emission areas R-EA, G-EA, and B-EA of the pixel area PA. For example, the green reflective electrode 200G is located on a different layer from the red reflective electrode 200R, and the blue reflective electrode 200B may be located on a different layer from the green reflective electrode 200G and the red reflective electrode 200R. The wavelength range of the light amplified between the reflective electrodes 200R, 200G, and 200B and the upper electrode 330 in each pixel area PA may be determined by the distances between the reflective electrodes 200R, 200G, and 200B and the upper electrode 330 in the pixel area PA. For example, the red reflective electrode 200R located in the red emission area R-EA may be located between the first planarization layer 131 and the second planarization layer 132, the green reflective electrode 200G located in the green emission area G-EA may be located between the second planarization layer 132 and the third planarization layer 133, and the blue reflective electrode 200B located in the blue emission area B-EA may be located on the third planarization layer 133.

An upper surface of the blue reflective electrode 200B opposite the element substrate 100 may be in direct contact with the lower electrode 310 in the blue emission area B-EA. For example, the thickness of the blue reflective electrode 200B may be the same as the thickness of the fourth planarization layer 134. The lower electrode 310 in each pixel area PA may include an area in contact with an upper surface of the fourth planarization layer 134 opposite the element substrate 100. For example, a side surface of the blue reflective electrode 200B may be surrounded by the fourth planarization layer 134. As a result, the overall thickness of the display device according to one or more embodiments of the present disclosure may be reduced.

An area located between the emission areas R-EA, G-EA, and B-EA may be defined as a non-emission area. For example, the fences 140 may be located in the non-emission area. A separation trench ST may be located in the non-emission area located between the fences 140. The separation trench ST may be formed in the element planarization layer 130. The separation trench ST may be located near the upper surface of the element planarization layer 130. For example, the separation trench ST may have a recess shape in which a part of the element planarization layer 130 is removed. The separation trench ST may be surrounded by the element planarization layer 130. An air gap may be formed in the separation trench ST. The light emitting unit 320 in each pixel area PA may be partially separated from the light emitting unit 320 in an adjacent pixel area PA by the fences 140 and the separation trench ST. For example, the light emitting unit 320 in each pixel area PA includes light emitting stacks and at least one charge generation layer located between the light emitting stacks, and the charge generation layer located on each pixel area PA may be separated from the charge generation layer located on an adjacent pixel area PA by the fences 140 and the separation trench ST. Accordingly, in the display device according to one or more embodiments of the present disclosure, leakage of the drive current applied to each pixel area PA through the charge generation layer may be prevented. Therefore, in the display device according to one or more embodiments of the present disclosure, malfunction of the light emitting element 300 located in each pixel area PA due to leakage current may be prevented.

An encapsulation structure 400 may be located on the light emitting element 300 in each pixel area PA. The encapsulation structure 400 may prevent damage to the light emitting element 300 located in each pixel area PA caused by external impact and moisture. The encapsulation structure 400 may have a multilayer structure. For example, the encapsulation structure 400 may include a first encapsulation layer 410, a second encapsulation layer 420, and a third encapsulation layer 430 stacked on the upper electrode 330 in order. Each of the first encapsulation layer 410, the second encapsulation layer 420, and the third encapsulation layer 430 may include an insulating material. The second encapsulation layer 420 may include a different material from the first encapsulation layer 410 and the third encapsulation layer 430. For example, each of the first encapsulation layer 410 and the third encapsulation layer 430 may be an inorganic encapsulation layer made of an inorganic insulating material, and the second encapsulation layer 420 may be an organic encapsulation layer made of an organic insulating material. Accordingly, in the display device according to one or more embodiments of the present disclosure, the height difference caused by the light emitting element 300 in each pixel area PA may be eliminated by the second encapsulation layer 420. For example, an upper surface of the third encapsulation layer 430 opposite the element substrate 100 may be flat.

Color filters 500R, 500G, and 500B may be located on the encapsulation structure 400. The color filters 500R, 500G, and 500B may overlap the emission areas R-EA, G-EA, and B-EA of the pixel areas PA. For example, light emitted from the light emitting element 300 in each pixel area PA may pass through one of the color filters 500R, 500G, and 500B. Light passing through the color filters 500R, 500G, and 500B located on each pixel area PA may exhibit the same color as the light emitted from the emission areas R-EA, G-EA, and B-EA of the pixel area PA. For example, the color filters 500R, 500G, and 500B may include a red color filter 500R overlapping the red emission area R-EA, a green color filter 500G overlapping the green emission area G-EA, and a blue color filter 500B overlapping the blue emission area B-EA. Accordingly, in the display device according to one or more embodiments of the present disclosure, color gamut may be improved. The color filters 500R, 500G, and 500B may be made of various materials. For example, each of the color filters 500R, 500G, and 500B may include a pigment. Therefore, the display device according to one or more embodiments of the present disclosure may have improved reliability at high temperatures.

The color filters 500R, 500G, and 500B may be located side by side. For example, a lower surfaces of each of the color filters 500R, 500G, and 500B facing the element substrate 100 may be in direct contact with an upper surface of the encapsulation structure 400. A side surface of each of the color filters 500R, 500G, and 500B may be in contact with adjacent one of the color filters 500R, 500G, and 500B. For example, the boundary of adjacent color filters 500R, 500G, and 500B may overlap the separation trench ST. Accordingly, in the display device according to one or more embodiments of the present disclosure, degradation in the quality of the image perceived by the user due to light that does not pass through the color filters 500R, 500G, and 500B may be prevented or at least reduced. That is, in the display device according to one or more embodiments of the present disclosure, light leakage may be prevented or at least reduced.

The pixel areas PA may be located side by side in a first direction (X) and a second direction (Y) perpendicular to the first direction (X). For example, the pixel areas PA may be disposed in a matrix form. The emission areas R-EA, G-EA, and B-EA of each pixel area PA may exhibit a different color than the emission areas R-EA, G-EA, and B-EA of the pixel area PA adjacent in the first direction (X). For example, in the display device according to one or more embodiments of the present disclosure, red emission areas R-EA, green emission areas G-EA, and blue emission areas B-EA may be repeatedly disposed in the first direction(X). The emission areas R-EA, G-EA, and B-EA of each pixel area PA may exhibit the same color as the emission areas R-EA, G-EA, and B-EA of the pixel area PA adjacent in the second direction (Y). For example, the color filters 500R, 500G, and 500B may extend in the second direction (Y). The display device according to one or more embodiments of the present disclosure may be a stripe type display device in which the color filters 500R, 500G, and 500B extending in the second direction (Y) are located side by side in the first direction (X). Meanwhile, a filter planarization layer may be located on the color filters 500R, 500G, and 500B. The filter planarization layer may protect the color filters 500R, 500G, and 500B from external impact while minimizing or at least reducing surface height differences between the color filters 500R, 500G, and 500B, thereby preventing or at least reducing the occurrence of stain caused by surface height differences.

Meanwhile, the display panel DP may be implemented through the following process. However, the structure described with reference to FIGS. 1 to 4 should be interpreted as an example of one of the structures of the display panel DP that can be used in the process described below.

FIG. 5 is a view showing a part of a process for manufacturing a display panel according to one or more embodiments of the present disclosure. FIG. 6 is a first example view showing a cover substrate shown in FIG. 5 according to one or more embodiments of the present disclosure. FIG. 7 is a second example view showing the cover substrate shown in FIG. 5 according to one or more embodiments of the present disclosure. FIG. 8 is a third example view showing the cover substrate shown in FIG. 5 according to one or more embodiments of the present disclosure.

As shown in FIG. 5, a plurality of display cells CELL each including an active area AA and a pad area PAD may be formed on the element substrate 100. The active areas AA of the display cells CELL may be implemented as the pixel areas PA described with reference to FIGS. 1 to FIG. 4. The pad area PAD may be implemented in the bezel area BZ described with reference to FIG. 1 so as to be separated from the active area AA. For example, the pad area PAD may include pads for electrical connection to the data drive circuit DD and the power supply circuit PU located outside the display panel DP as shown in FIG. 1. The pads may be electrically connected to the active area AA through lines for supplying signals and voltages.

A cover substrate 600 may be formed on the element substrate 100 where the plurality of display cells CELL is formed. The cover substrate 600 may be made of glass; however, the present disclosure is not limited thereto. The cover substrate 600 may include a plurality of open areas OPN corresponding to the plurality of pad areas PAD formed on the element substrate 100. That is, each of the open areas OPN may have a shape that exposes the pad area PAD when viewed from an upper surface of the cover substrate 600, such as a rectangular shape.

The open areas OPN may be implemented based on laser modification chemical etching (LMCE) technology, which controls the phase change of the cover substrate 600 using a laser and induces differences in etching speed. For reference, LMCE technology offers advantages such as excellent thin film processing for cracks/chips, freedom from hole size/pitch restrictions for drilling, and the ability to simultaneously perform drilling, cutting, slimming, and healing, thereby enhancing productivity and quality.

Therefore, when the open areas OPN are formed using LMCE technology, a smooth cutting surface may be achieved based on the shape visible on a plane. That is, when glass is selected as the cover substrate 600, the phenomenon of glass chipping may be eliminated, enabling the smooth formation of the open areas OPN (preventing or at least reducing quality degradation). In addition, when the open areas OPN are formed using LMCE technology, rounding of sharp corners is also possible.

As shown in FIGS. 5 and 6, the element substrate 100 may have a circular shape and may include a slightly different number of display cells CELL in each area. Therefore, the open areas OPN in each area of the cover substrate 600 may have slightly different lengths, as illustrated in the example. However, if the element substrate 100 and the cover substrate 600 are not circular or elliptical but square or other shapes with all sides of equal length, the open areas OPN may have the same length in all areas. Therefore, the disposition structure of the open areas OPN on the cover substrate 600 may vary depending on the shape of the element substrate 100 and the shape (including the length) of the pad areas PAD.

As shown in FIGS. 5 and 7, the cover substrate 600 may include a plurality of open lines OPL in addition to the open areas OPN that open the pad areas PAD disposed on the element substrate 100. The open lines OPL are similar to the open areas OPN in that the open lines are formed through the cover substrate 600, but the open lines are different from the open areas in that the open lines do not open a wide area but open a small area like a solid line (fine processing treatment or micro processing treatment). The open lines OPL may be located so as to correspond to cutting lines (Sawing Line) defined for cutting the display cells CELL into cell units. That is, the open lines OPL may be defined as a pre-processing structure configured to provide advantages such as simplifying a sawing process during a cell unit cutting process. The open lines OPL may also be formed using LMCE technology described above.

Meanwhile, when forming the open lines OPL, it is preferable to set the length such that the cover substrate 600 remains intact and all parts thereof are connected to each other. For example, the open line OPL may have a length that maintains a minimum spacing SPC between the open area OPN and the open line OPL.

As shown in FIGS. 5 and 8, the cover substrate 600 may include a plurality of cutting lines CUL in addition to the open areas OPN that open the pad areas PAD disposed on the element substrate 100. The cutting lines CUL differ from the open areas OPN in that the cutting lines are formed as fine recesses so as not to be formed through the cover substrate 600. The cutting lines CUL may be located so as to correspond to sawing lines defined for cutting the display cells CELL into cell units. That is, the cutting lines CUL may be defined as a pre-processing structure configured to facilitate the sawing process during the cell unit cutting process.

Meanwhile, when forming the cutting lines CUL, it is preferable to set the length such that the cover substrate 600 remains intact and all parts thereof are connected to each other. For example, the cutting line CUL may have a depth that does not exceed half the thickness of the cover substrate 600. Meanwhile, while FIG. 8 shows the cutting line CUL in a V-shaped V-cut form, the present disclosure is not limited thereto.

As shown in FIGS. 6 to 8, when forming the open areas OPN on the cover substrate 600, process time may be reduced during a cutting process using a blade. Furthermore, when the open lines OPL or the cutting lines CUL are further formed in addition to the open areas OPN, the cutting process may be simplified or eliminated, thereby reducing costs associated with equipment investment.

FIG. 9 is a view showing a process for cutting the bonded an element substrate and the cover substrate into cell units according to one or more embodiments of the present disclosure. FIGS. 10 to 13 are sectional views showing the cell unit cutting process according to one or more embodiments of the present disclosure.

As shown in FIG. 9, the element substrate 100 and the cover substrate 600 may be bonded through a bonding process and then undergo a cutting process so as to be cut into cell units. The cutting process may be performed along the open areas OPN and the pre-set cutting lines after a blade 800 is aligned on the cover substrate 600. The following description focuses on a sectional view to aid in understanding the structural configuration of the display cells after the cutting process.

As shown in FIG. 10, the element substrate 100 and the cover substrate 600 may include a plurality of display cells such as a first display cell CELL1 and a second display cell CELL2. The element substrate 100 and the cover substrate 600 may be bonded with an adhesive layer 700 interposed therebetween through a lamination process. At this time, the adhesive layer 700 may cover both the active areas AA and the pad areas PAD located on the element substrate 100.

As shown in FIG. 11, when the element substrate 100 and the cover substrate 600 are bonded based on the adhesive layer 700, the adhesive layer 700 may fill the open areas OPN of the cover substrate 600 and extend to the upper surface of the cover substrate 600. However, this is merely an example, and the adhesive layer 700 may fill the open areas OPN depending on the pressure applied during lamination, but may not extend to the upper surface of the cover substrate 600.

As shown in FIG. 12, the plurality of display cells, such as the first display cell CELL1 and the second display cell CELL2, provided based on the bonded element substrate 100 and cover substrate 600, may be cut and separated from each other through the cell unit cutting process using the blade 800.

As shown in FIG. 13, according to one or more embodiments, in the first display cell CELL1, the adhesive layer 700 located in the pad area PAD may be removed through a removal process. As a result, the pads included in the pad area PAD may be exposed externally to facilitate electrical connection to the data drive circuit DD and the power supply circuit PU of FIG. 1. Here, the adhesive layer 700 may be removed using a wet etching method; however, the present disclosure is not limited thereto.

Meanwhile, even if the adhesive layer 700 remaining in the pad area PAD and the periphery thereof is removed from the first display cell CELL1, a part filled up to the open area OPN of the cover substrate 600 may remain in the form of a residual adhesive layer 700R. The reason is as follows: the adhesive layer 700 is cured through a curing process after lamination between the element substrate 100 and the cover substrate 600, but only the part formed on the cover substrate 600 may remain depending on the etching ratio, since the element substrate 100 and the cover substrate 600 are made of different materials (the element substrate is made of a semiconductor material and the cover substrate is made of glass). That is, the residual adhesive layer 700R may be the same material as the adhesive layer 700 (a material derived from the adhesive layer).

The residual adhesive layer 700R remaining on the side surface of the open area OPN of the cover substrate 600 may protect the pad area PAD from foreign substances, as well as prevent or at least reduce moisture penetration, thereby enhancing protection against external environments. Additionally, the residual adhesive layer 700R may have a different remaining area depending on the area (or size) of the pad area PAD, moisture prevention, or protective capability.

Meanwhile, FIG. 13 shows an example where the residual adhesive layer 700R remaining on the side surface of the open area OPN is present only in a small amount, corresponding to an area smaller than that of the open area OPN; however, the present disclosure is not limited thereto.

FIG. 14 is a view showing the structure visible in the section of a first display cell according to one or more embodiments of the present disclosure, and FIG. 15 is a view showing the structure visible in the section of a first display cell according to one or more other embodiments of the present disclosure.

As shown in FIG. 14, according to one or more embodiments, the residual adhesive layer 700R may remain as formed, filling the open area OPN of the cover substrate 600. That is, the residual adhesive layer 700R may remain corresponding to the area of the open area OPN. In this case, the pad area PAD may have a surrounding environment (or upper environment) in which the pad area can be protected from foreign substances. In one or more embodiments, a process where the part filled in the open area OPN is not intentionally removed during wet etching to remove the adhesive layer 700 may be performed.

As shown in FIG. 15, according to one or more other embodiments, the residual adhesive layer 700R may remain while filling a part of the open area OPN of the cover substrate 600. A resin layer 900 configured to cover the residual adhesive layer 700R may be located in the remaining part of the open area OPN. For example, the residual adhesive layer 700R may be formed so as to occupy half of the side surface of the open area OPN, and the resin layer 900 may be formed to occupy the remaining half of the side surface of the open area OPN; however, the present disclosure is not limited thereto. That is, the ratio of the part occupied by the residual adhesive layer 700R to the part occupied by the resin layer 900 may vary depending on the process conditions.

The resin layer 900 may be intentionally formed to provide a surrounding environment (or upper environment) that can protect the pad area PAD from foreign substances. The resin layer 900 may perform a moisture-proofing function to prevent or at least reduce moisture penetration into the pad area PAD and the periphery thereof.

In addition, the resin layer 900 may be formed when sufficient pressure is not applied during lamination between the element substrate 100 and the cover substrate 600, whereby the adhesive layer 700 fills the open area OPN but does not extend to the upper surface of the cover substrate 600. That is, the resin layer 900 may be formed through an additional process during lamination between the element substrate 100 and the cover substrate 600.

As is apparent from the above description, the present disclosure has the effect that it is possible to simplify a process involved in manufacturing a display panel based on a method for processing a cover substrate using an LMCE process, thereby reducing equipment investment costs while improving productivity and quality. In addition, the present disclosure has the effect that it is possible to simplify a cutting process based on open areas formed on the cover substrate, thereby reducing processing time, and it is possible to simplify the process such that some steps of the process can be omitted. Furthermore, the present disclosure has the effect that it is possible to allow an adhesive layer or a resin layer used during lamination between display cells cut into cell units to remain in the open areas formed on the cover substrate, thereby protecting pad areas from foreign substances as well as enhancing protection against external air by preventing or at least reducing moisture penetration.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a schematic view of a display device according to one or more embodiments of the present disclosure.

FIG. 2 is an enlarged view of area K1 in FIG. 1.

FIG. 3 is a view showing a circuit of a pixel area in the display device according to one or more embodiments of the present disclosure.

FIG. 4 is a sectional view taken along line I-I’ in FIG. 2.

FIG. 5 is a view showing a part of a process for manufacturing a display panel according to one or more embodiments of the present disclosure.

FIG. 6 is a first example view showing a cover substrate shown in FIG. 5 according to one or more embodiments of the present disclosure.

FIG. 7 is a second example view showing the cover substrate shown in FIG. 5 according to one or more embodiments of the present disclosure.

FIG. 8 is a third example view showing the cover substrate shown in FIG. 5 according to one or more embodiments of the present disclosure.

FIG. 9 is a view showing a process for cutting the bonded an element substrate and the cover substrate into cell units according to one or more embodiments of the present disclosure.

FIGS. 10 to 13 are sectional views showing the cell unit cutting process according to one or more embodiments of the present disclosure.

FIG. 14 is a view showing the structure visible in the section of a first display cell according to one or more embodiments of the present disclosure.

FIG. 15 is a view showing the structure visible in the section of a first display cell according to one or more other embodiments of the present disclosure.

### DETAILED DESCRIPTION

The object and technical configuration of the present disclosure and the effects based thereon will be more clearly understood from the following detailed description with reference to the accompanying drawings, which show embodiments of the present disclosure. The embodiments of the present disclosure are provided to enable the technical ideas of the present disclosure to be fully conveyed to those skilled in the art, and the present disclosure may be embodied in other forms without limitation to the embodiments described herein.

In addition, throughout the specification, the same components are denoted by the same reference numerals, and in the drawings, the lengths and thicknesses of layers or areas may be exaggerated for convenience. Furthermore, when a first component is described as being “on” a second component, this includes not only the case in which the first component is located on the second component in direct contact therewith but also the case in which a third component is located between the first and second components.

Terms such as “first” and “second” may be used herein to describe various components, and are used to distinguish one component from another component. However, a first component and a second component may be arbitrarily named according to the convenience of those skilled in the art without departing from the scope of the present disclosure.

The terms used in the present disclosure are provided only to describe specific embodiments, and do not limit the present disclosure. Singular forms are intended to include plural forms as well, unless the context clearly indicates otherwise. In the present disclosure, it should be understood that the terms “includes,” “has,” etc. specify the presence of stated features, numbers, steps, operations, elements, components, or combinations thereof, but do not preclude the presence or addition of one or more other features, numbers, steps, operations, elements, components, or combinations thereof.

In addition, all terms, including technical and scientific terms, have the same meanings as those commonly understood by one of ordinary skill in the art to which the present disclosure pertains, unless defined otherwise. Commonly used terms, such as those defined in typical dictionaries, should be interpreted as being consistent with the contextual meaning of the relevant art, and are not to be construed in an ideal or overly formal sense unless expressly defined to the contrary.

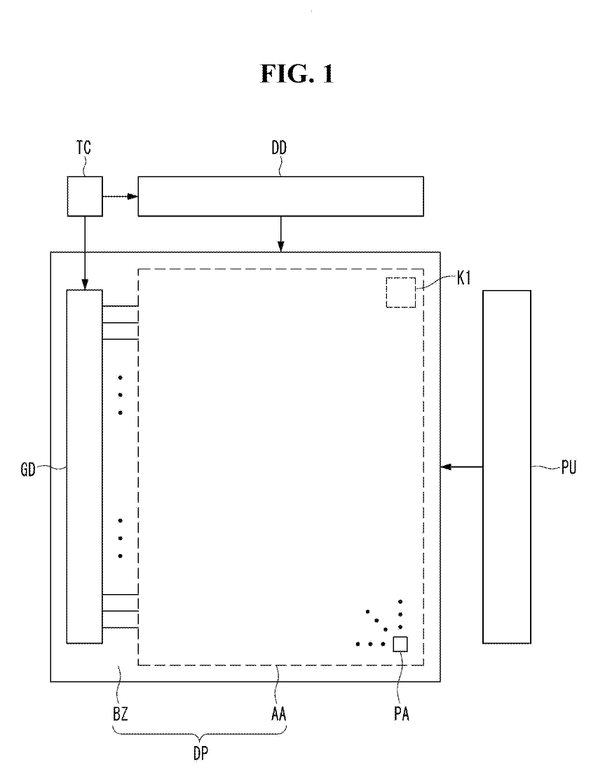

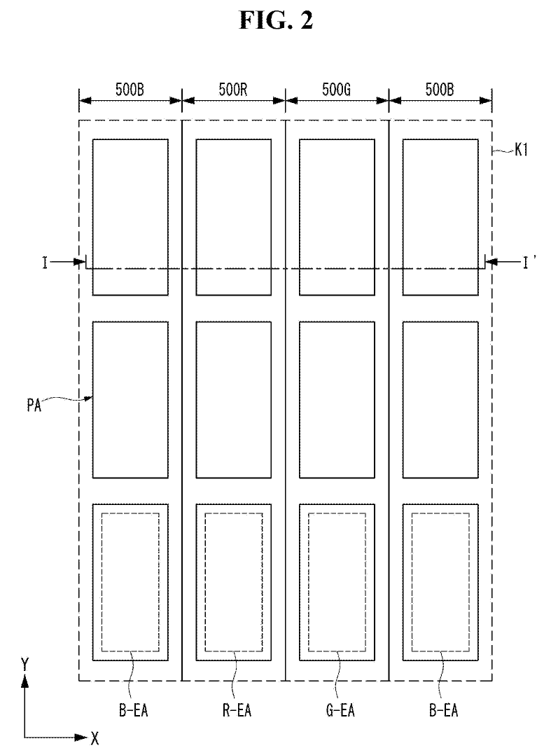

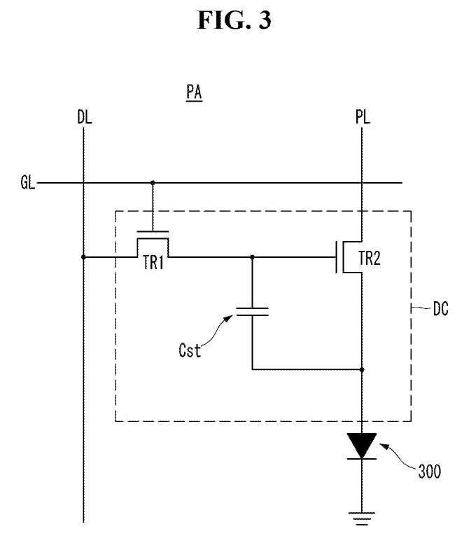

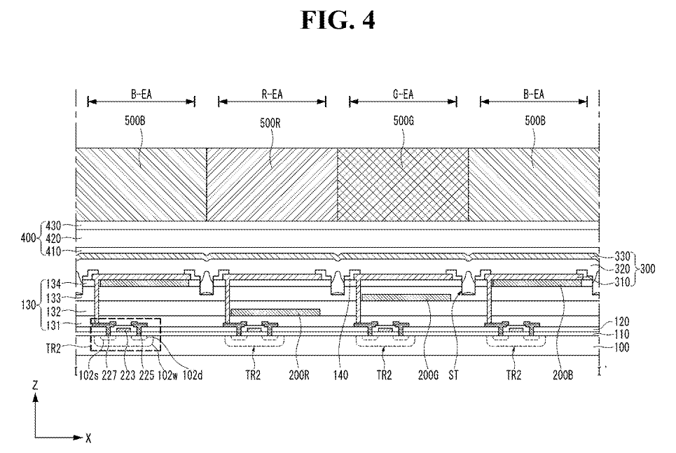

FIG. 1 is a schematic view of a display device according to one or more embodiments of the present disclosure. FIG. 2 is an enlarged view of area K1 in FIG. 1. FIG. 3 is a view showing a circuit of a pixel area in the display device according to one or more embodiments of the present disclosure. FIG. 4 is a sectional view taken along line I-I’ in FIG. 2.

Referring to FIGS. 1 to 4, the display device according to one or more embodiments of the present disclosure may include a display panel DP. The display panel DP may generate an image to be provided to a user. For example, pixel areas PA may be located in the display panel DP. Various signals may be applied to the pixel areas PA through signal lines GL, DL, and PL. The signal lines GL, DL, and PL may include a gate line GL for applying a gate signal, a data line DL for applying a data signal, and a power voltage supply line PL for supplying a power voltage.

The display panel DP may include an active area AA where the pixel areas PA are located and a bezel area BZ located outside the active area AA. The signal lines GL, DL, and PL may be electrically connected to the pixel areas PA via the bezel area BZ. For example, the active area AA may be surrounded by the bezel area BZ. A gate drive circuit GD electrically connected to the gate line GL, a data drive circuit DD electrically connected to the data line DL, a power supply circuit PU electrically connected to the power voltage supply line PL, and a timing control circuit TC configured to control the gate drive circuit GD and the data drive circuit DD may be located outside the active area AA. At least one of the gate drive circuit GD, the data drive circuit DD, the power supply circuit PU, and the timing control circuit TC may be located in the bezel area BZ. For example, the display device according to one or more embodiments of the present disclosure may be a gate in panel (GIP) type display device in which the gate drive circuit GD is formed in the bezel area BZ.

Each pixel area PA may implement a specific color. For example, a pixel drive circuit DC electrically connected to the signal lines GL, DL, and PL and a light emitting element 300 electrically connected to the pixel drive circuit DC may be located in each pixel area PA. The pixel drive circuit DC and the light emitting element 300 of each pixel area PA may be supported by an element substrate 100. The element substrate 100 may include various materials. For example, the element substrate 100 may be a wafer made of a semiconductor material such as silicon.

The pixel drive circuit DC may supply a drive current corresponding to a data signal to the light emitting element 300 in accordance with a gate signal using power voltage. The drive current supplied to the light emitting element 300 by the pixel drive circuit DC may be maintained for one frame. For example, the pixel drive circuit DC may include a first thin film transistor TR1, a second thin film transistor TR2, and a storage capacitor Cst.

The first thin film transistor TR1 may transmit a data signal to the second thin film transistor TR2 in accordance with a gate signal. For example, the first thin film transistor TR1 may function as a switching thin film transistor. The first thin film transistor TR1 may include a first well area, a first drain area, a first source area, a first gate electrode, a first drain electrode, and a first source electrode. For example, the first gate electrode may be electrically connected to the gate line GL, and the first drain electrode may be electrically connected to the data line DL.

The second thin film transistor TR2 may generate a drive current corresponding to a data signal using power voltage. For example, the second thin film transistor TR2 may function as a drive thin film transistor. The second thin film transistor TR2 may include a second well area 102w, a second drain area 102d, a second source area 102s, a second gate electrode 223, a second drain electrode 225, and a second source electrode 227. For example, the second gate electrode 223 may be electrically connected to the first source electrode, and the second drain electrode 225 may be electrically connected to the power voltage supply line PL.

The second well area 102w, the second drain area 102d, and the second source area 102s may be formed in the element substrate 100. Each of the second well area 102w, the second drain area 102d, and the second source area 102s may include a conductive dopant. For example, a process for forming the second well area 102w, the second drain area 102d, and the second source area 102s may include a process for doping a part of the element substrate 100 with a conductive dopant. The second drain area 102d and the second source area 102s may include a different type of conductive dopant than the second well area 102w. For example, the second well area 102w may include an N-type dopant, and each of the second drain area 102d and the second source area 102s may include a P-type dopant. The second drain area 102d and the second source area 102s may be located in the second well area 102w.

The second well area 102w may include a different type of conductive dopant than the first well area. Each of the second drain area 102d and the second source area 102s may include a different type of conductive dopant than the first drain area and the first source area. For example, the second well area 102w may include the same type of conductive dopant as the first drain area and the first source area, and each of the second drain area 102d and the second source area 102s may include the same type of conductive dopant as the first well area. Accordingly, in the display device according to one or more embodiments of the present disclosure, the second thin film transistor TR2 may have different characteristics than the first thin film transistor TR1. The second well area 102w may be formed simultaneously with the first drain area and the first source area, and the second drain area 102d and the second source area 102s may be formed simultaneously with the first well area. Therefore, in the display device according to one or more embodiments of the present disclosure, process efficiency may be improved.

The second gate electrode 223 may be located on the element substrate 100. For example, the second gate electrode 223 may overlap a part of the second well area 102w. The second gate electrode 223 may include a conductive material. For example, the second gate electrode 223 may include a metal such as aluminum (Al), chromium (Cr), copper (Cu), molybdenum (Mo), titanium (Ti), or tungsten (W). A part of the second well area 102w overlapping the second gate electrode 223 may be located between the second drain area 102d and the second source area 102s. The second gate electrode 223 may be spaced apart from the element substrate 100. The second gate electrode 223 may be insulated from the element substrate 100. For example, a part of the second well area 102w overlapping the second gate electrode 223 between the second drain area 102d and the second source area 102s may have an electrical conductivity corresponding to the voltage of z signal applied to the second gate electrode 223. A part of the second well area 102w overlapping the second gate electrode 223 between the second drain area 102d and the second source area 102s may function as a channel area of the second thin film transistor TR2.

The second gate electrode 223 may include the same material as the first gate electrode. The second gate electrode 223 may be located on the same layer as the first gate electrode. The second gate electrode 223 may be formed through the same process as the first gate electrode. For example, the second gate electrode 223 may be formed simultaneously with the first gate electrode.

The second drain electrode 225 may be located on the element substrate 100. The second drain electrode 225 may be electrically connected to the second drain area 102d. The second drain electrode 225 may include a conductive material. For example, the second drain electrode 225 may include a metal such as aluminum (Al), chromium (Cr), copper (Cu), molybdenum (Mo), titanium (Ti), or tungsten (W). The second drain electrode 225 may be spaced apart from the element substrate 100. The second drain electrode 225 may be insulated from the second gate electrode 223. For example, the second drain electrode 225 may be located on a different layer from the second gate electrode 223. The second drain electrode 225 may include a different material from the second gate electrode 223.

The second drain electrode 225 may include the same material as the first drain electrode. The second drain electrode 225 may be located on the same layer as the first drain electrode. The second drain electrode 225 may be formed through the same process as the first drain electrode. For example, the second drain electrode 225 may be formed simultaneously with the first drain electrode.

The second source electrode 227 may be located on the element substrate 100. The second source electrode 227 may be electrically connected to the second source area 102s. The second source electrode 227 may include a conductive material. For example, the second source electrode 227 may include a metal such as aluminum (Al), chromium (Cr), copper (Cu), molybdenum (Mo), titanium (Ti), or tungsten (W). The second source electrode 227 may be spaced apart from the element substrate 100. The second source electrode 227 may be insulated from the second gate electrode 223. For example, the second source electrode 227 may be located on a different layer from the second gate electrode 223. The second source electrode 227 may include a different material from the second gate electrode 223.

The second source electrode 227 may be located on the same layer as the second drain electrode 225. The second source electrode 227 may include the same material as the second drain electrode 225. The second source electrode 227 may be formed through the same process as the second drain electrode 225. For example, the second source electrode 227 may be formed simultaneously with the second drain electrode 225. The second source electrode 227 may be spaced apart from the second drain electrode 225.

The second source electrode 227 may include the same material as the first source electrode. The second source electrode 227 may be located on the same layer as the first source electrode. The second source electrode 227 may be formed through the same process as the first source electrode. For example, the second source electrode 227 may be formed simultaneously with the first source electrode.

The storage capacitor Cst may maintain the voltage of a signal applied to the second gate electrode 223 for one frame. The storage capacitor Cst may have a stack structure of capacitor electrodes. For example, the storage capacitor Cst may have a structure in which a first capacitor electrode electrically connected to the second gate electrode 223 and a second capacitor electrode electrically connected to the second source electrode are stacked. The storage capacitor Cst may be formed using the process for forming the first thin film transistor TR1 and the second thin film transistor TR2. For example, the first capacitor electrode may be formed simultaneously with the second gate electrode 223, and the second capacitor electrode may be formed simultaneously with the second source electrode 227. Accordingly, in the display device according to one or more embodiments of the present disclosure, process efficiency may be improved.

At least one insulating layer 110, 120, 130, and 140 configured to prevent unnecessary electrical connection may be provided on the element substrate 100. For example, a gate insulating layer 110, an interlayer insulating layer 120, an element planarization layer 130, and fences 140 may be located on the element substrate 100.

The gate insulating layer 110 may be located close to the element substrate 100. The second gate electrode 223 in each pixel area PA may be insulated from the element substrate 100 by the gate insulating layer 110. For example, the first gate electrode and the second gate electrode 223 in each pixel area PA may be located on the gate insulating layer 110 that completely covers an upper surface of the element substrate 100. The gate insulating layer 110 may include an insulating material. For example, the gate insulating layer 110 may be an inorganic insulating layer made of an inorganic insulating material such as silicon oxide (SiOx) or silicon nitride (SiNx). The second gate electrode 223 in each pixel area PA may have the same level as the first gate electrode in each pixel area PA. For example, the distance between the element substrate 100 and the second gate electrode 223 in each pixel area PA may be the same as the distance between the element substrate 100 and the first gate electrode in each pixel area PA. The gate insulating layer 110 may be a linear insulating layer having a certain thickness.

The interlayer insulating layer 120 may be located on the gate insulating layer 110. The second drain electrode 225 and second source electrode 227 in each pixel area PA may be insulated from the second gate electrode 223 in the pixel area PA by the interlayer insulating layer 120. For example, the interlayer insulating layer 120 may cover the first gate electrode and the second gate electrode 223 in each pixel area PA. The first drain electrode, the first source electrode, the second drain electrode 225, and the second source electrode 227 in each pixel area PA may be located on the interlayer insulating layer 120. The interlayer insulating layer 120 may include an insulating material. For example, the interlayer insulating layer 120 may be an inorganic insulating layer made of an inorganic insulating material such as silicon oxide (SiOx) or silicon nitride (SiNx).

The element planarization layer 130 may be located on the interlayer insulating layer 120. The element planarization layer 130 may eliminate the height difference caused by the pixel drive circuit DC in each pixel area PA. For example, the first drain electrode, the first source electrode, the second drain electrode 225, and the second source electrode 227 in each pixel area PA may be covered by the element planarization layer 130. An upper surface of the element planarization layer 130 opposite the element substrate 100 may be flat. For example, the upper surface of the element planarization layer 130 may be parallel to the upper surface of the element substrate 100. The element planarization layer 130 may include an insulating material. The element planarization layer 130 may include a material having high fluidity. For example, the element planarization layer 130 may be an organic insulating layer made of an organic insulating material. The element planarization layer 130 may include a first planarization layer 131, a second planarization layer 132, a third planarization layer 133, and a fourth planarization layer 134 stacked in order; however, the present disclosure is not limited thereto.

The light emitting element 300 in each pixel area PA may be located on the element planarization layer 130. The light emitting element 300 in each pixel area PA may emit light of a specific color. For example, the light emitting element 300 in each pixel area PA may include a lower electrode 310, a light emitting unit 320, and an upper electrode 330 stacked on the element planarization layer 130 in order.

Each of the lower electrode 310 and the upper electrode 330 may include a conductive material. The upper electrode 330 may include a different material from the lower electrode 310. For example, the lower electrode 310 may be a transparent electrode made of a transparent conductive material such as ITO or IZO, and the upper electrode 330 may be a semi-transparent electrode made of a thin metal such as silver (Ag) or magnesium (Mg). The upper electrode 330 may have a different work function from the lower electrode 310. For example, the work function of the upper electrode 330 may be lower than that of the lower electrode 310. Accordingly, in the display device according to one or more embodiments of the present disclosure, the lower electrode 310 may function as an anode, and the upper electrode 330 may function as a cathode.

The light emitting unit 320 may generate light with a luminance corresponding to the voltage difference between the lower electrode 310 and the upper electrode 330. For example, the light emitting unit 320 may include an emission material layer (EML). The emission material layer may include an organic emission material, an inorganic emission material, or a hybrid emission material. For example, the display device according to one or more embodiments of the present disclosure may be an organic light emitting display device including an organic emission material.

The light emitting unit 320 may have a multilayer structure. For example, the light emitting unit 320 may further include at least one of a hole injection layer (HIL), a hole transport layer (HTL), an electron transport layer (ETL), and an electron injection layer (EIL). Accordingly, in the display device according to one or more embodiments of the present disclosure, the efficiency of the light emitting unit 320 may be improved.

The fences 140 may be located on the element planarization layer 130. Each of the fences 140 may include an insulating material. Each fence 140 may have a certain thickness. For example, each of the fences 140 may be an inorganic insulating layer made of an inorganic insulating material. The fences 140 may define emission areas R-EA, G-EA, and B-EA in each pixel area PA. The emission areas R-EA, G-EA, and B-EA of each pixel area PA may refer to areas where light is emitted. For example, in the emission areas R-EA, G-EA, and B-EA of each pixel area PA, the light emitting unit 320 may be in direct contact with the lower electrode 310 and the upper electrode 330.

The lower electrode 310 in each pixel area PA may be spaced apart from the lower electrode 310 in an adjacent pixel area PA. The lower electrode 310 in each pixel area PA may be insulated from the lower electrode 310 in an adjacent pixel area PA by the fences 140. For example, an edge of the lower electrode 310 located in each pixel area PA may be covered by the fences 140. A part of the lower electrode 310 overlapping the emission areas R-EA, G-EA, and B-EA of each pixel area PA may be in direct contact with the upper surface of the element planarization layer 130.

A drive current generated by the pixel drive circuit DC in each pixel area PA may be applied to the lower electrode 310 in the pixel area PA. For example, the lower electrode 310 in each pixel area PA may be in direct contact with the second source electrode 227 in the pixel area PA through the element planarization layer 130. The connection point between the lower electrode 310 and the second source electrode 227 located in each pixel area PA may be located outside the emission areas R-EA, G-EA, and B-EA defined in the pixel area PA. For example, the connection point between the lower electrode 310 and the second source electrode 227 located in each pixel area PA may overlap one of the fences 140. Accordingly, in the display device according to one or more embodiments of the present disclosure, luminance variation caused by the position of generation of light emitted from the emission areas R-EA, G-EA, and B-EA of each pixel area PA may be prevented.

The light generated by the light emitting unit 320 in each pixel area PA may exhibit the same color as the light generated by the light emitting unit 320 in an adjacent pixel area PA. For example, the light emitting unit 320 in each pixel area PA may generate white light. The light emitting unit 320 in each pixel area PA may have the same stack structure as the light emitting unit 320 in an adjacent pixel area PA. For example, the emission material layer in each pixel area PA may include the same material as the emission material layer in an adjacent pixel area PA. The light emitting unit 320 in each pixel area PA may be formed simultaneously with the light emitting unit 320 in an adjacent pixel area PA.

A signal applied to the upper electrode 330 in each pixel area PA may be the same as the signal applied to the upper electrode 330 in an adjacent pixel area PA. For example, the upper electrode 330 in each pixel area PA may be electrically connected to the upper electrode 330 in an adjacent pixel area PA. The upper electrode 330 in each pixel area PA may include the same material as the upper electrode 330 in an adjacent pixel area PA. The upper electrode 330 in each pixel area PA may be formed through the same process as the upper electrode 330 in an adjacent pixel area PA. For example, the upper electrode 330 in each pixel area PA may be formed simultaneously with the upper electrode 330 in an adjacent pixel area PA. The upper electrode 330 in each pixel area PA may be in direct contact with the upper electrode 330 in an adjacent pixel area PA. Accordingly, in the display device according to one or more embodiments of the present disclosure, a process for forming the upper electrode 330 in each pixel area PA may be simplified.

An image provided to the user by the light emitted from the emission areas R-EA, G-EA, and B-EA of the pixel areas PA may include various colors. For example, the emission areas R-EA, G-EA, and B-EA of each pixel area PA may be a red emission area R-EA that emits red light indicating red, a green emission area G-EA that emits green light indicating green, and a blue emission area B-EA that emits blue light indicating blue. A micro-cavity structure may be formed in the emission areas R-EA, G-EA, and B-EA of each pixel area PA. For example, reflective electrodes 200R, 200G, and 200B may be located between the pixel drive circuit DC and the lower electrode 310 in each pixel area PA.

Accordingly, in the display device according to one or more embodiments of the present disclosure, a part of the light generated by the light emitting unit 320 in each pixel area PA having a wavelength range corresponding to the color implemented by the emission areas R-EA, G-EA, and B-EA of the pixel area PA may be amplified between the reflective electrodes 200R, 200G, and 200B and the upper electrode 330 in the pixel area PA. For example, in the display device according to one or more embodiments of the present disclosure, red light may be amplified between the red reflective electrode 200R in the red emission area R-EA and the upper electrode 330, green light may be amplified between the green reflective electrode 200G in the green emission area G-EA and the upper electrode 330, and blue light may be amplified between the blue reflective electrode 200B in the blue emission area B-EA and the upper electrode 330. The light amplified between the reflective electrodes 200R, 200G, and 200B and the upper electrode 330 in each pixel area PA may be emitted through the upper electrode 330 in the pixel area PA.

The positions of the reflective electrodes 200R, 200G, and 200B in the emission areas R-EA, G-EA, and B-EA of each pixel area PA may vary depending on the colors implemented by the emission areas R-EA, G-EA, and B-EA of the pixel area PA. For example, the green reflective electrode 200G is located on a different layer from the red reflective electrode 200R, and the blue reflective electrode 200B may be located on a different layer from the green reflective electrode 200G and the red reflective electrode 200R. The wavelength range of the light amplified between the reflective electrodes 200R, 200G, and 200B and the upper electrode 330 in each pixel area PA may be determined by the distances between the reflective electrodes 200R, 200G, and 200B and the upper electrode 330 in the pixel area PA. For example, the red reflective electrode 200R located in the red emission area R-EA may be located between the first planarization layer 131 and the second planarization layer 132, the green reflective electrode 200G located in the green emission area G-EA may be located between the second planarization layer 132 and the third planarization layer 133, and the blue reflective electrode 200B located in the blue emission area B-EA may be located on the third planarization layer 133.

An upper surface of the blue reflective electrode 200B opposite the element substrate 100 may be in direct contact with the lower electrode 310 in the blue emission area B-EA. For example, the thickness of the blue reflective electrode 200B may be the same as the thickness of the fourth planarization layer 134. The lower electrode 310 in each pixel area PA may include an area in contact with an upper surface of the fourth planarization layer 134 opposite the element substrate 100. For example, a side surface of the blue reflective electrode 200B may be surrounded by the fourth planarization layer 134. As a result, the overall thickness of the display device according to one or more embodiments of the present disclosure may be reduced.

An area located between the emission areas R-EA, G-EA, and B-EA may be defined as a non-emission area. For example, the fences 140 may be located in the non-emission area. A separation trench ST may be located in the non-emission area located between the fences 140. The separation trench ST may be formed in the element planarization layer 130. The separation trench ST may be located near the upper surface of the element planarization layer 130. For example, the separation trench ST may have a recess shape in which a part of the element planarization layer 130 is removed. The separation trench ST may be surrounded by the element planarization layer 130. An air gap may be formed in the separation trench ST. The light emitting unit 320 in each pixel area PA may be partially separated from the light emitting unit 320 in an adjacent pixel area PA by the fences 140 and the separation trench ST. For example, the light emitting unit 320 in each pixel area PA includes light emitting stacks and at least one charge generation layer located between the light emitting stacks, and the charge generation layer located on each pixel area PA may be separated from the charge generation layer located on an adjacent pixel area PA by the fences 140 and the separation trench ST. Accordingly, in the display device according to one or more embodiments of the present disclosure, leakage of the drive current applied to each pixel area PA through the charge generation layer may be prevented. Therefore, in the display device according to one or more embodiments of the present disclosure, malfunction of the light emitting element 300 located in each pixel area PA due to leakage current may be prevented.

An encapsulation structure 400 may be located on the light emitting element 300 in each pixel area PA. The encapsulation structure 400 may prevent damage to the light emitting element 300 located in each pixel area PA caused by external impact and moisture. The encapsulation structure 400 may have a multilayer structure. For example, the encapsulation structure 400 may include a first encapsulation layer 410, a second encapsulation layer 420, and a third encapsulation layer 430 stacked on the upper electrode 330 in order. Each of the first encapsulation layer 410, the second encapsulation layer 420, and the third encapsulation layer 430 may include an insulating material. The second encapsulation layer 420 may include a different material from the first encapsulation layer 410 and the third encapsulation layer 430. For example, each of the first encapsulation layer 410 and the third encapsulation layer 430 may be an inorganic encapsulation layer made of an inorganic insulating material, and the second encapsulation layer 420 may be an organic encapsulation layer made of an organic insulating material. Accordingly, in the display device according to one or more embodiments of the present disclosure, the height difference caused by the light emitting element 300 in each pixel area PA may be eliminated by the second encapsulation layer 420. For example, an upper surface of the third encapsulation layer 430 opposite the element substrate 100 may be flat.

Color filters 500R, 500G, and 500B may be located on the encapsulation structure 400. The color filters 500R, 500G, and 500B may overlap the emission areas R-EA, G-EA, and B-EA of the pixel areas PA. For example, light emitted from the light emitting element 300 in each pixel area PA may pass through one of the color filters 500R, 500G, and 500B. Light passing through the color filters 500R, 500G, and 500B located on each pixel area PA may exhibit the same color as the light emitted from the emission areas R-EA, G-EA, and B-EA of the pixel area PA. For example, the color filters 500R, 500G, and 500B may include a red color filter 500R overlapping the red emission area R-EA, a green color filter 500G overlapping the green emission area G-EA, and a blue color filter 500B overlapping the blue emission area B-EA. Accordingly, in the display device according to one or more embodiments of the present disclosure, color gamut may be improved. The color filters 500R, 500G, and 500B may be made of various materials. For example, each of the color filters 500R, 500G, and 500B may include a pigment. Therefore, the display device according to one or more embodiments of the present disclosure may have improved reliability at high temperatures.

The color filters 500R, 500G, and 500B may be located side by side. For example, a lower surfaces of each of the color filters 500R, 500G, and 500B facing the element substrate 100 may be in direct contact with an upper surface of the encapsulation structure 400. A side surface of each of the color filters 500R, 500G, and 500B may be in contact with adjacent one of the color filters 500R, 500G, and 500B. For example, the boundary of adjacent color filters 500R, 500G, and 500B may overlap the separation trench ST. Accordingly, in the display device according to one or more embodiments of the present disclosure, degradation in the quality of the image perceived by the user due to light that does not pass through the color filters 500R, 500G, and 500B may be prevented or at least reduced. That is, in the display device according to one or more embodiments of the present disclosure, light leakage may be prevented or at least reduced.

The pixel areas PA may be located side by side in a first direction (X) and a second direction (Y) perpendicular to the first direction (X). For example, the pixel areas PA may be disposed in a matrix form. The emission areas R-EA, G-EA, and B-EA of each pixel area PA may exhibit a different color than the emission areas R-EA, G-EA, and B-EA of the pixel area PA adjacent in the first direction (X). For example, in the display device according to one or more embodiments of the present disclosure, red emission areas R-EA, green emission areas G-EA, and blue emission areas B-EA may be repeatedly disposed in the first direction(X). The emission areas R-EA, G-EA, and B-EA of each pixel area PA may exhibit the same color as the emission areas R-EA, G-EA, and B-EA of the pixel area PA adjacent in the second direction (Y). For example, the color filters 500R, 500G, and 500B may extend in the second direction (Y). The display device according to one or more embodiments of the present disclosure may be a stripe type display device in which the color filters 500R, 500G, and 500B extending in the second direction (Y) are located side by side in the first direction (X). Meanwhile, a filter planarization layer may be located on the color filters 500R, 500G, and 500B. The filter planarization layer may protect the color filters 500R, 500G, and 500B from external impact while minimizing or at least reducing surface height differences between the color filters 500R, 500G, and 500B, thereby preventing or at least reducing the occurrence of stain caused by surface height differences.

Meanwhile, the display panel DP may be implemented through the following process. However, the structure described with reference to FIGS. 1 to 4 should be interpreted as an example of one of the structures of the display panel DP that can be used in the process described below.

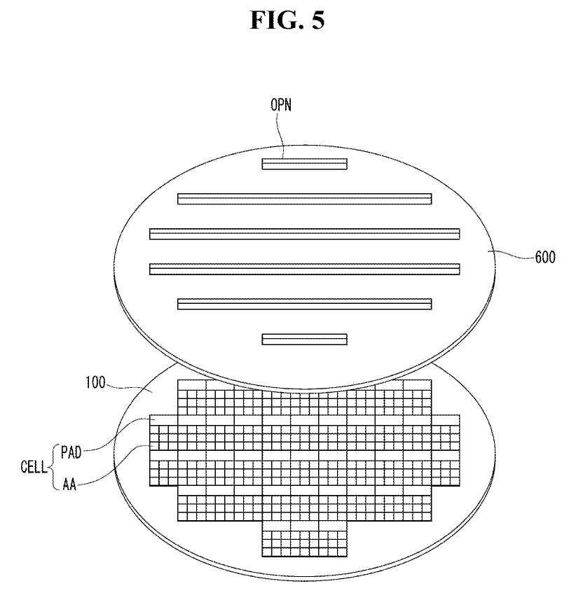

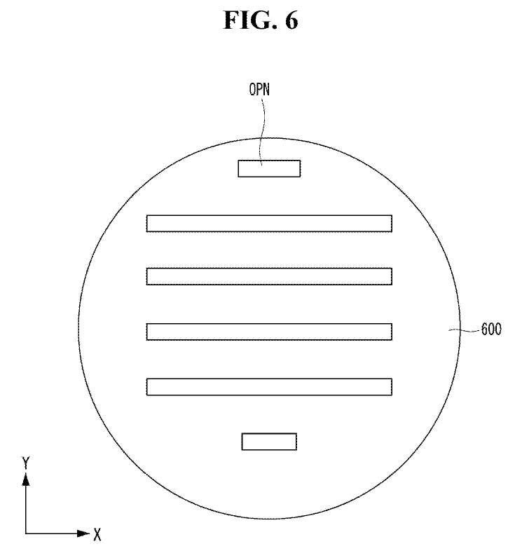

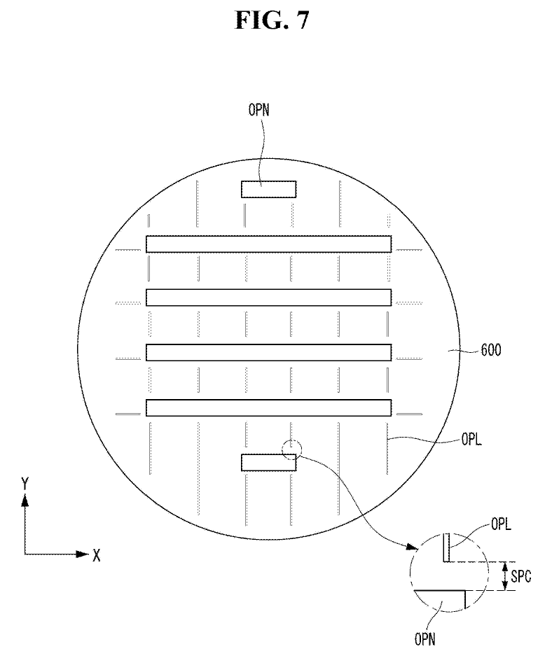

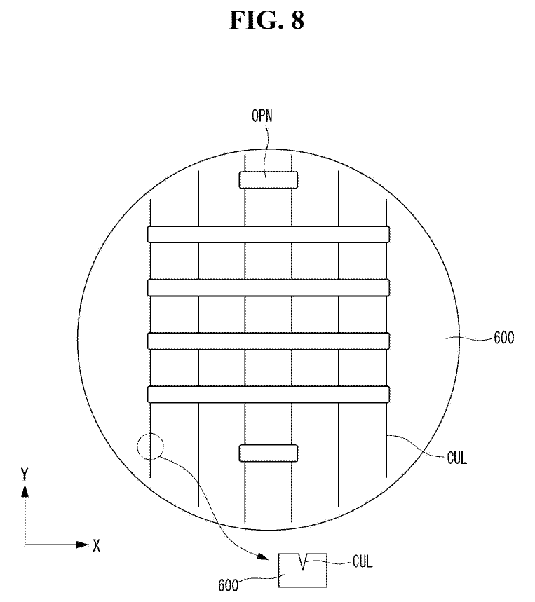

FIG. 5 is a view showing a part of a process for manufacturing a display panel according to one or more embodiments of the present disclosure. FIG. 6 is a first example view showing a cover substrate shown in FIG. 5 according to one or more embodiments of the present disclosure. FIG. 7 is a second example view showing the cover substrate shown in FIG. 5 according to one or more embodiments of the present disclosure. FIG. 8 is a third example view showing the cover substrate shown in FIG. 5 according to one or more embodiments of the present disclosure.

As shown in FIG. 5, a plurality of display cells CELL each including an active area AA and a pad area PAD may be formed on the element substrate 100. The active areas AA of the display cells CELL may be implemented as the pixel areas PA described with reference to FIGS. 1 or FIG. 4. The pad area PAD may be implemented in the bezel area BZ described with reference to FIG. 1 so as to be separated from the active area AA. For example, the pad area PAD may include pads for electrical connection to the data drive circuit DD and the power supply circuit PU located outside the display panel DP as shown in FIG. 1. The pads may be electrically connected to the active area AA through lines for supplying signals and voltages.

A cover substrate 600 may be formed on the element substrate 100 where the plurality of display cells CELL is formed. The cover substrate 600 may be made of glass; however, the present disclosure is not limited thereto. The cover substrate 600 may include a plurality of open areas OPN corresponding to the plurality of pad areas PAD formed on the element substrate 100. That is, each of the open areas OPN may have a shape that exposes the pad area PAD when viewed from an upper surface of the cover substrate 600, such as a rectangular shape.

The open areas OPN may be implemented based on laser modification chemical etching (LMCE) technology, which controls the phase change of the cover substrate 600 using a laser and induces differences in etching speed. For reference, LMCE technology offers advantages such as excellent thin film processing for cracks/chips, freedom from hole size/pitch restrictions for drilling, and the ability to simultaneously perform drilling, cutting, slimming, and healing, thereby enhancing productivity and quality.

Therefore, when the open areas OPN are formed using LMCE technology, a smooth cutting surface may be achieved based on the shape visible on a plane. That is, when glass is selected as the cover substrate 600, the phenomenon of glass chipping may be eliminated, enabling the smooth formation of the open areas OPN (preventing or at least reducing quality degradation). In addition, when the open areas OPN are formed using LMCE technology, rounding of sharp corners is also possible.

As shown in FIGS. 5 and 6, the element substrate 100 may have a circular shape and may include a slightly different number of display cells CELL in each area. Therefore, the open areas OPN in each area of the cover substrate 600 may have slightly different lengths, as illustrated in the example. However, if the element substrate 100 and the cover substrate 600 are not circular or elliptical but square or other shapes with all sides of equal length, the open areas OPN may have the same length in all areas. Therefore, the disposition structure of the open areas OPN on the cover substrate 600 may vary depending on the shape of the element substrate 100 and the shape (including the length) of the pad areas PAD.

As shown in FIGS. 5 and 7, the cover substrate 600 may include a plurality of open lines OPL in addition to the open areas OPN that open the pad areas PAD disposed on the element substrate 100. The open lines OPL are similar to the open areas OPN in that the open lines are formed through the cover substrate 600, but the open lines are different from the open areas in that the open lines do not open a wide area but open a small area like a solid line (fine processing treatment or micro processing treatment). The open lines OPL may be located so as to correspond to cutting lines (Sawing Line) defined for cutting the display cells CELL into cell units. That is, the open lines OPL may be defined as a pre-processing structure configured to provide advantages such as simplifying a sawing process during a cell unit cutting process. The open lines OPL may also be formed using LMCE technology described above.

Meanwhile, when forming the open lines OPL, it is preferable to set the length such that the cover substrate 600 remains intact and all parts thereof are connected to each other. For example, the open line OPL may have a length that maintains a minimum spacing SPC between the open area OPN and the open line OPL.

As shown in FIGS. 5 and 8, the cover substrate 600 may include a plurality of cutting lines CUL in addition to the open areas OPN that open the pad areas PAD disposed on the element substrate 100. The cutting lines CUL differ from the open areas OPN in that the cutting lines are formed as fine recesses so as not to be formed through the cover substrate 600. The cutting lines CUL may be located so as to correspond to sawing lines defined for cutting the display cells CELL into cell units. That is, the cutting lines CUL may be defined as a pre-processing structure configured to facilitate the sawing process during the cell unit cutting process.

Meanwhile, when forming the cutting lines CUL, it is preferable to set the length such that the cover substrate 600 remains intact and all parts thereof are connected to each other. For example, the cutting line CUL may have a depth that does not exceed half the thickness of the cover substrate 600. Meanwhile, while FIG. 8 shows the cutting line CUL in a V-shaped V-cut form, the present disclosure is not limited thereto.

As shown in FIGS. 6 to 8, when forming the open areas OPN on the cover substrate 600, process time may be reduced during a cutting process using a blade. Furthermore, when the open lines OPL or the cutting lines CUL are further formed in addition to the open areas OPN, the cutting process may be simplified or eliminated, thereby reducing costs associated with equipment investment.

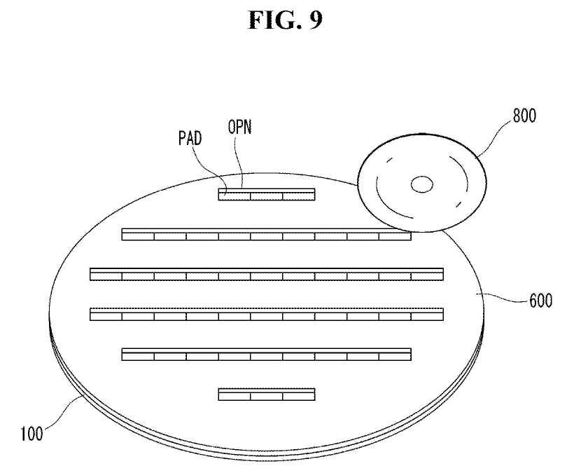

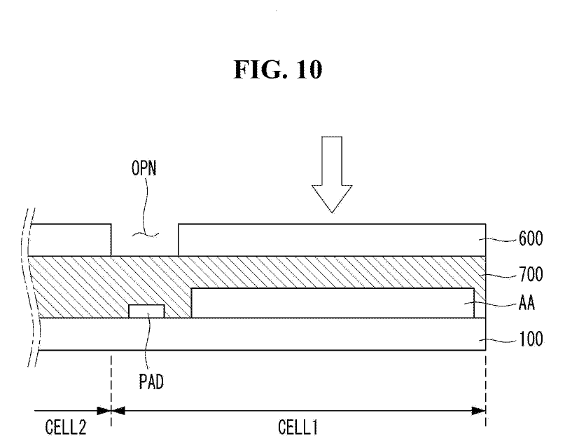

FIG. 9 is a view showing a process for cutting the bonded an element substrate and the cover substrate into cell units according to one or more embodiments of the present disclosure. FIGS. 10 to 13 are sectional views showing the cell unit cutting process according to one or more embodiments of the present disclosure.

As shown in FIG. 9, the element substrate 100 and the cover substrate 600 may be bonded through a bonding process and then undergo a cutting process so as to be cut into cell units. The cutting process may be performed along the open areas OPN and the pre-set cutting lines after a blade 800 is aligned on the cover substrate 600. The following description focuses on a sectional view to aid in understanding the structural configuration of the display cells after the cutting process.

As shown in FIG. 10, the element substrate 100 and the cover substrate 600 may include a plurality of display cells such as a first display cell CELL1 and a second display cell CELL2. The element substrate 100 and the cover substrate 600 may be bonded with an adhesive layer 700 interposed therebetween through a lamination process. At this time, the adhesive layer 700 may cover both the active areas AA and the pad areas PAD located on the element substrate 100.

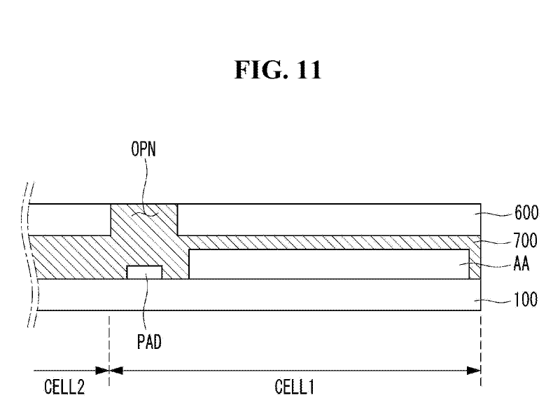

As shown in FIG. 11, when the element substrate 100 and the cover substrate 600 are bonded based on the adhesive layer 700, the adhesive layer 700 may fill the open areas OPN of the cover substrate 600 and extend to the upper surface of the cover substrate 600. However, this is merely an example, and the adhesive layer 700 may fill the open areas OPN depending on the pressure applied during lamination, but may not extend to the upper surface of the cover substrate 600.

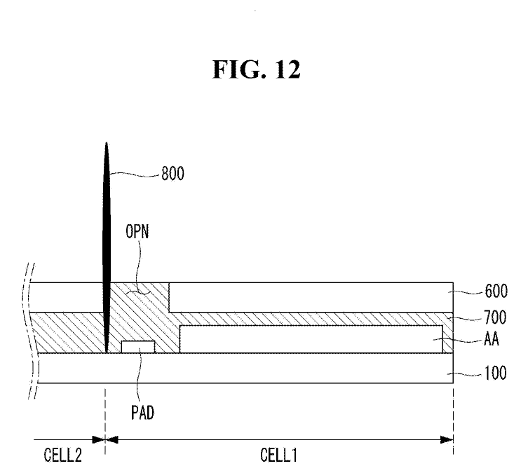

As shown in FIG. 12, the plurality of display cells, such as the first display cell CELL1 and the second display cell CELL2, provided based on the bonded element substrate 100 and cover substrate 600, may be cut and separated from each other through the cell unit cutting process using the blade 800.

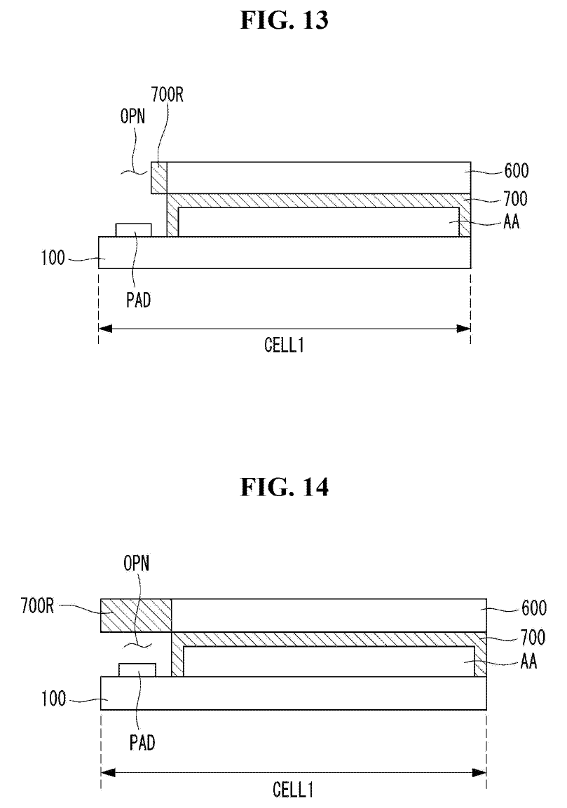

As shown in FIG. 13, according to one or more embodiments, in the first display cell CELL1, the adhesive layer 700 located in the pad area PAD may be removed through a removal process. As a result, the pads included in the pad area PAD may be exposed externally to facilitate electrical connection to the data drive circuit DD and the power supply circuit PU of FIG. 1. Here, the adhesive layer 700 may be removed using a wet etching method; however, the present disclosure is not limited thereto.

Meanwhile, even if the adhesive layer 700 remaining in the pad area PAD and the periphery thereof is removed from the first display cell CELL1, a part filled up to the open area OPN of the cover substrate 600 may remain in the form of a residual adhesive layer 700R. The reason is as follows: the adhesive layer 700 is cured through a curing process after lamination between the element substrate 100 and the cover substrate 600, but only the part formed on the cover substrate 600 may remain depending on the etching ratio, since the element substrate 100 and the cover substrate 600 are made of different materials (the element substrate is made of a semiconductor material and the cover substrate is made of glass). That is, the residual adhesive layer 700R may be the same material as the adhesive layer 700 (a material derived from the adhesive layer).

The residual adhesive layer 700R remaining on the side surface of the open area OPN of the cover substrate 600 may protect the pad area PAD from foreign substances, as well as prevent or at least reduce moisture penetration, thereby enhancing protection against external environments. Additionally, the residual adhesive layer 700R may have a different remaining area depending on the area (or size) of the pad area PAD, moisture prevention, or protective capability.

Meanwhile, FIG. 13 shows an example where the residual adhesive layer 700R remaining on the side surface of the open area OPN is present only in a small amount, corresponding to an area smaller than that of the open area OPN; however, the present disclosure is not limited thereto.

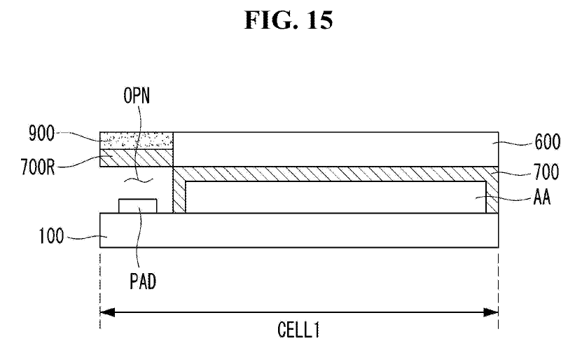

FIG. 14 is a view showing the structure visible in the section of a first display cell according to one or more embodiments of the present disclosure, and FIG. 15 is a view showing the structure visible in the section of a first display cell according to one or more other embodiments of the present disclosure.

As shown in FIG. 14, according to one or more embodiments, the residual adhesive layer 700R may remain as formed, filling the open area OPN of the cover substrate 600. That is, the residual adhesive layer 700R may remain corresponding to the area of the open area OPN. In this case, the pad area PAD may have a surrounding environment (or upper environment) in which the pad area can be protected from foreign substances. In one or more embodiments, a process where the part filled in the open area OPN is not intentionally removed during wet etching to remove the adhesive layer 700 may be performed.

As shown in FIG. 15, according to one or more other embodiments, the residual adhesive layer 700R may remain while filling a part of the open area OPN of the cover substrate 600. A resin layer 900 configured to cover the residual adhesive layer 700R may be located in the remaining part of the open area OPN. For example, the residual adhesive layer 700R may be formed so as to occupy half of the side surface of the open area OPN, and the resin layer 900 may be formed to occupy the remaining half of the side surface of the open area OPN; however, the present disclosure is not limited thereto. That is, the ratio of the part occupied by the residual adhesive layer 700R to the part occupied by the resin layer 900 may vary depending on the process conditions.

The resin layer 900 may be intentionally formed to provide a surrounding environment (or upper environment) that can protect the pad area PAD from foreign substances. The resin layer 900 may perform a moisture-proofing function to prevent or at least reduce moisture penetration into the pad area PAD and the periphery thereof.

In addition, the resin layer 900 may be formed when sufficient pressure is not applied during lamination between the element substrate 100 and the cover substrate 600, whereby the adhesive layer 700 fills the open area OPN but does not extend to the upper surface of the cover substrate 600. That is, the resin layer 900 may be formed through an additional process during lamination between the element substrate 100 and the cover substrate 600.

As is apparent from the above description, the present disclosure has the effect that it is possible to simplify a process involved in manufacturing a display panel based on a method for processing a cover substrate using an LMCE process, thereby reducing equipment investment costs while improving productivity and quality. In addition, the present disclosure has the effect that it is possible to simplify a cutting process based on open areas formed on the cover substrate, thereby reducing processing time, and it is possible to simplify the process such that some steps of the process can be omitted. Furthermore, the present disclosure has the effect that it is possible to allow an adhesive layer or a resin layer used during lamination between display cells cut into cell units to remain in the open areas formed on the cover substrate, thereby protecting pad areas from foreign substances as well as enhancing protection against external air by preventing or at least reducing moisture penetration.

What is claimed is:

1. A display device, comprising:
an element substrate;
an active area comprising a pixel drive circuit and a light emitting element located on the element substrate;
a pad area located on the element substrate; and
a cover substrate located on the element substrate, the cover substrate covering the active area and the pad area,
wherein the cover substrate comprises an open area exposing the pad area and a residual adhesive layer that remains on a side surface of the open area.

2. The display device according to claim 1, wherein the residual adhesive layer includes a same material as an adhesive layer configured to facilitate lamination between the element substrate and the cover substrate.

3. The display device according to claim 1, wherein an area of the residual adhesive layer is equal to an area of the open area.

4. The display device according to claim 1, wherein an area of the residual adhesive layer is less than an area of the open area.

5. The display device according to claim 1, further comprising a resin layer formed on the side surface of the open area and located on the residual adhesive layer.

6. A method of manufacturing a display device, the method comprising:
forming an active area and a pad area that is electrically connected to the active area on an element substrate as a display cell unit, the active area including a pixel drive circuit and a light emitting element;
forming an adhesive layer that covers the active area and the pad area on the element substrate;
aligning a cover substrate on the element substrate;
laminating the element substrate and the cover substrate using the adhesive layer; and
performing a cutting process to cut the element substrate and the cover substrate so as to be separated as the display cell unit,
wherein the cover substrate comprises an open area exposing the pad area and a residual adhesive layer that remains on a side surface of the open area.

7. The method according to claim 6, wherein the residual adhesive layer includes a same material as the adhesive layer configured to facilitate lamination between the element substrate and the cover substrate.

8. The method according to claim 6, wherein the cover substrate comprises a plurality of open lines that correspond to an area defined as a cutting line during the cutting process, and
wherein the plurality of open lines are implemented so as to be formed through the cover substrate.

9. The method according to claim 6, wherein the cover substrate comprises a plurality of cutting lines that correspond to an area defined as a cutting line during the cutting process, and
wherein the plurality of cutting lines are implemented in a shape of recesses that are not formed through the cover substrate.

10. The method according to claim 6, wherein an area of the residual adhesive layer is equal to or less than an area of the open area.

11. The method according to claim 6, wherein the display device comprises a resin layer formed on the side surface of the open area and located on the residual adhesive layer.
